(19) United States
(12) Patent Application Publication
(10) Pub. No.: US 2003/0139047 A1
(43) Pub. Date: Jul. 24, 2003

(54) Metal polishing slurry having a static etch inhibitor and method of formulation

(76) Inventors: Terence M. Thomas, Newark, DE (US); Stephan DeNardi, Wilmington, DE (US); Wade Godfrey, Landenberg, PA (US)

Correspondence Address: Rodel Holdings, Inc., Suite 1300, 1105 North Market Street, Wilmington, DE, 19899, US

(21) Appl. No.: 10/056,342

(22) Filed: Jan. 24, 2002

(51) Int. Cl. H01L 21/302; H01L 21/461

(52) U.S. Cl. 438/692

(57) ABSTRACT

A metal polishing slurry having a static etch inhibitor and method for polishing a substrate while inhibiting static etching during the polishing of a substrate. The slurry composition includes an iodate-free halogenated inhibiting compound added to a generic slurry to form a resultant slurry. The substrate is polished using the resultant slurry, which inhibits the static etching of the substrate being polished. Also provided is a metal polishing slurry for inhibiting static etch comprising an oxidizer, a complexing agent, and an iodate-free halogenated inhibiting compound.

### FIELD OF THE INVENTION

The present invention relates, generally, to the chemical-mechanical metal polishing of semiconductors and, more particularly, to metal polishing slurries having a halogenated molecular ion inhibiting agent to reduce the static etch removal rate during the metal polishing process.

### BACKGROUND

In chemical-mechanical metal polishing (“CMP”), metal polishing slurries are used to both etch and polish a metal surface. Competing chemical reactions take place during CMP. The first of these is an oxidation reaction. During oxidation, the oxidizing agent acts to form a metallic oxide with the surface of the substrate. The second reaction is the complexing reaction. In this reaction, the complexing agent actively dissolves the oxide film growing on the substrate from the oxidation reaction. It has been discovered more recently that sometimes, a third, inhibiting reaction takes place. During an inhibiting reaction, the inhibiting compound forms a surface film that blocks the dissolution of the metallic oxide on the surface of the substrate.

The static etching of metals is a common side-effect of CMP. During the CMP process, the metal polishing slurry that remains on the surface of the substrate continues to etch the substrate, beyond the effects of the CMP. Sometimes, static etch is desired; however, in most semiconductor processes, static etch should be minimized. Static etch may also contribute to surface defects such as pitting and keyholing. These surface defects significantly affect the final properties of the semiconductor device and hamper its usefulness. Static etch inhibitors have therefore been investigated.

Halogen oxides have been used as oxidation agents in metal polishing slurries. The halo-oxides chemically react with the substrate surface to form a metal oxide. This oxide is easily removed from the surface of the substrate, which not only removes material from the substrate but also polishes its surface. In further investigation of iodate-based slurries, however, iodate solutions in controlled concentrations were found to act as an inhibitor of static etching when not actively polishing lodate-based slurries used in CMP have had the ability to inhibit the static etching process. While iodate-based slurries succeed in inhibiting static etching, they also have the undesirable property of turning any surface they contact yellow. This is undesirable for the processing of the semiconductor as well as for cosmetic reasons. Accordingly, there is an existing need for a metal polishing slurry having a static etch inhibitor that will efficiently inhibit the etching process, while not affecting the conductivity or cosmetic properties of the polished surface.

### BRIEF SUMMARY

According to one aspect of the present invention, there is provided a metal polishing method for inhibiting static etching of a substrate that includes providing a metal polishing slurry composition, adding an iodate-free halogenated inhibiting compound to the metal polishing slurry to form a resultant slurry, and polishing the substrate while substantially inhibiting static etching.

According to another aspect of the present invention, there is provided a metal polishing slurry for inhibiting static etching of a substrate that includes an oxidizer, a complexing agent, and an iodate-free halogenated inhibiting compound.

### DETAILED DESCRIPTION OF PREFERED EMBODIMENTS

The present invention relates to metal polishing slurries having a static etch inhibitor and methods of preparation of these metal polishing slurries. The inventive metal polishing slurry incorporates halogenated molecular ions other than iodate compounds as inhibitors. Preferably, in CMP slurries of the present invention, the inhibitors are molecular ions of chlorine and bromine. More preferably, the inhibitors are molecular ions comprising chlorate (ClO₃⁻) and bromate (BrO₃⁻). These halogenated molecular ions can generally be added to a slurry composition as a solid powder compound. Such compounds generally include alkali metals such as potassium or alkaline earth metals such as magnesium. In a preferred embodiment, the solid powder compound used is potassium chlorate (KClO₃), or potassium bromate (KBrO₃), or the like. In another embodiment, combinations of these compounds are added to a slurry composition. Alkaline halogenated compounds are readily available commercially, or may be synthesized by conventional methods as known to those skilled in the art.

By industry convention, a compound with an etch removal rate of less than about 200 angstroms/minute is classified as an effective etch inhibitor. Therefore, in accordance with the invention, enough of the halogenated inhibiting compound is added to the slurry to achieve this goal. The amount of halogenated inhibiting compound necessary will vary based on the type of slurry and the particular halogenated inhibiting compound. Preferably, the concentration of halogenated inhibiting compound in the metal polishing slurry does not exceed about the maximum solubility of the halogenated inhibiting compound. In some cases, exceeding this concentration can leave solid, undissolved particles of the halogenated inhibiting compound in the slurry solution. Undissolved particles of the halogenated inhibitor can interfere with the polishing and etching abilities of the slurry.

In accordance with the present invention, the inhibitor concentration preferably ranges from a minimally effective concentration up to about the maximum solubility limit in the particular slurry. The solubility limit of the halogenated inhibiting compound depends on the polishing slurry itself. In general, the solubility limit can range from about 1.8 wt % to about 22 wt % concentration in the slurry. Preferably, the inhibitor concentration ranges from about 0.01 wt % to about 15 wt % concentration; more preferably, a range of about 0.1 wt % to 5 wt % concentration.

In accordance with the invention, a halogenated inhibitor is introduced to one of several different metal polishing slurries. A typical metal polishing slurry includes an oxidizer and a complexing agent. A metal polishing slurry may also contain an abrasive agent. The oxidizer is a chemical compound such as hydrogen peroxide, potassium ferrocyanide, potassium dichromate, vanadium trioxide, hypochlorous acid, sodium hypochlorite, potassium hypochlorite, calcium hypochlorite, ferric nitrate, ammonium persulfate, ammonium nitrate, potassium nitrate, potassium permanganate, ammonium hydroxide or combinations thereof. The oxidizer engages in a reduction-oxidation chemical reaction with the metal being polished to form an oxide layer on the metal surface. The oxidizer concentration is about 1 wt % to about 8 wt % oxidizer and, more preferably, about 2 wt % to about 4.5 wt % oxidizer.

The complexing agent, on the other hand, is generally a carboxylic acid, which chemically removes the oxide layer from the substrate. For example, the complexing agent is a chemical compound such as malonic acid, lactic acid, sulfosalicylic acid (“SSA”), formic acid, acetic acid, propanoic acid, butanoic acid, pentanoic acid, hexanoic acid, heptanoic acid, octanoic acid, nonanoic acid, and mixtures thereof. The complexing agent concentration is about 1 wt % to about 3 wt %.

An abrasive agent may also be added to mechanically remove the oxide layer. Abrasive agents are generally metallic oxides. For example, silica, alumina, silicon carbide, silicon nitride, iron oxide, ceria, or a combination thereof are typically employed as abrasive agents in a metal polishing slurry.

Many substrates commonly used in semiconductor fabrication can be polished using a metal polishing slurry having a static etch inhibitor according to the method of the present invention. In one embodiment, the slurry is used in a CMP process to remove a layer of tungsten. Alternatively, the slurry of the present invention can be used to remove other metal layers, such as copper, tantalum, tantalum nitride, titanium, titanium nitride and the like.

The slurry compositions according to the present invention preferably have an acidic pH. In a preferred embodiment, the composition has a pH that is greater than about 1. More preferably, the pH of the resultant slurry solution is between about 2 and about 4. The pH of the solution is measured by conventional methods after mixing the inhibitor into the slurry, and can be adjusted by adding a base, such as ammonium hydroxide, or a mineral acid, such as nitric acid.

Without further elaboration, it is believed that one skilled in the art can, using the description above, utilize the present invention to its fullest extent. The following example, therefore, is intended to be merely illustrative and is not intended to limit the invention.

### EXAMPLE

Potassium chlorate was added in differing weight percentages to a generic slurry. The composition of the generic slurry is set forth in Table I.

TABLE I
Generic Slurry Composition
In Water

| | | |
|---|---|---|
| Hydrogen Peroxide | about 4 | wt % |
| Ferric Nitrate | about 0.01 | wt % |
| Malonic Acid | about 0.07 | wt % |
| Lactic Acid | about 1.5 | wt % |
| SSA | about 0.01 | wt % |

The pH of the resultant slurry was adjusted to about 3 with ammonium hydroxide. The resultant slurry was then used to etch and polish standard tungsten substrates via CMP. Substrate thickness was measured over time. The change in thickness was plotted against the time of etching and the slope of the graph was measured to determine the etching rate. The static etch rate data are shown below in Table II.

TABLE II
Etch Rate of Tungsten
Metal Polishing Slurry at pH = 3
Potassium Chlorate Etch Inhibitor

| KClO₃ wt. % | Static Etch Rate (angstroms/min.) |
|---|---|
| 0 | 340 |
| 0.01 | 200 |
| 0.1 | 126 |
| 1 | 70 |

The data in Table II show that the removal rate of tungsten can be significantly reduced to an industry-desirable range by forming a 0.01% potassium chlorate slurry solution. Further, potassium chlorate addition was able to further enhance the static etch inhibiting ability of the solution. Again, the precise amount of potassium chlorate needed to reach the 200 angstrom/minute static etching rate is dependent on the particular slurry. For example, a particularly acidic slurry solution using KClO₃ may require a different concentration of halogenated inhibiting compound to reduce the static etching rate below 200 angstrom/minute than a more basic slurry solution.

Thus it is apparent that there has been disclosed a static etch inhibitor that fully provides the advantages set forth above. Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the present invention all such variations and modifications as fall within the scope of the appended claims and equivalents thereof.

1. A polishing method for inhibiting static etching of a substrate comprising:
providing a metal polishing slurry composition;
adding an iodate-free halogenated inhibiting compound to said metal polishing slurry to form a resultant metal polishing slurry; and
polishing a substrate, while substantially inhibiting static etching of said substrate.

2. The method of claim 1, wherein adding a halogenated inhibiting compound comprises adding a compound having a molecular ion selected from the group consisting of bromate (BrO₃⁻), chlorate (ClO₃⁻), and a combination thereof.

3. The method of claim 1, wherein adding a halogenated inhibiting compound comprises adding a compound selected from the group consisting of potassium bromate (KBrO₃), potassium chlorate (KClO₃), and a combination thereof.

4. The method of claim 1, wherein adding a halogenated inhibiting compound comprises adding an amount of halogenated inhibiting compound less than about the amount required to form a fully saturated solution.

5. The method of claim 1, wherein adding a halogenated inhibiting compound comprises adding a sufficient amount of halogenated inhibiting compound such that the said resultant slurry solution has an etching removal rate below about 200 angstroms/minute.

6. The method of claim 1, wherein adding a halogenated inhibiting compound comprises adding a sufficient amount of halogenated inhibiting compound to form a resultant slurry solution with a pH greater than about 1.

7. The method of claim 6, wherein adding a halogenated inhibiting compound comprises adding a sufficient amount of halogenated inhibiting compound to form a resultant slurry solution with a pH between about 2 and about 4.

8. The method of claim 1, wherein performing a static etch comprises performing a static etch maintaining a removal rate less than about 200 Angstroms/Minute.

9. The method of claim 1, wherein performing a static etch comprises performing a static etch on a tungsten substrate.

10. A metal polishing slurry for inhibiting the static etching of a substrate comprising:
an oxidizer;
a complexing agent; and
an inhibitor,
wherein said inhibitor comprises an iodate-free halogenated inhibiting compound.

11. The metal polishing slurry of claim 10, further comprising an abrasive agent.

12. The metal polishing slurry of claim 11, wherein the oxidizer comprises a compound selected from the group consisting of hydrogen peroxide, potassium ferrocyanide, potassium dichromate, vanadium trioxide, hypochlorous acid, sodium hypochlorite, potassium hypochlorite, calcium hypochlorite, ferric nitrate, ammonium persulfate, ammonium nitrate, potassium nitrate, potassium permanganate, ammonium hydroxide and combinations thereof.

13. The metal polishing slurry of claim 11, wherein the complexing agent comprises a compound selected from the group consisting of malonic acid, lactic acid, SSA, formic acid, acetic acid, propanoic acid, butanoic acid, pentanoic acid, hexanoic acid, heptanoic acid, octanoic acid, nonanoic acid, and combinations thereof.

14. The metal polishing slurry of claim 11, wherein the abrasive agent is selected from the group consisting of silica, alumina, silicon carbide, silicon nitride, iron oxide, ceria, and combinations thereof.

15. The metal polishing slurry of claim 11, wherein said inhibitor comprises a molecular ion selected from the group consisting of bromate (BrO₃⁻), chlorate (ClO₃⁻), and a combination thereof.

16. The metal polishing slurry of claim 15, wherein said inhibitor comprises a compound selected from the group consisting of potassium bromate (KBrO₃), potassium chlorate (KClO₃), and a combination thereof.

17. The metal polishing slurry of claim 10, wherein said inhibitor comprises an amount of halogenated inhibiting compound less than about the amount required to form a fully saturated solution.

18. The metal polishing slurry of claim 10, wherein said slurry comprises an etch removal rate of less than about 200 angstroms/minute.

19. The metal polishing slurry of claim 10, wherein said slurry comprises a pH of greater than about 1.

20. The metal polishing slurry of claim 19, wherein said slurry comprises a pH of about 2 to about 4.

21. The metal polishing slurry of claim 10, wherein said oxidizer is present at a concentration of about 1 wt % to about 8 wt %.

22. The metal polishing slurry of claim 21, wherein said oxidizer is present at a concentration of about 2 wt % to about 4.5 wt %.

23. The metal polishing slurry of claim 10, wherein said complexing agent is present at a concentration of about 1 wt % to about 3 wt %.

24. The metal polishing slurry of claim 10, wherein said oxidizer comprises an iodate-free oxidizer.

25. A metal polishing slurry for inhibiting the static etching of a substrate comprising:
hydrogen peroxide;
ferric nitrate;
malonic acid;
lactic acid;
SSA; and
potassium chlorate.

26. The metal polishing slurry of claim 25, wherein:
hydrogen peroxide is present at a concentration of about percent by weight;
ferric nitrate is present at a concentration of about 0.01 percent by weight;
malonic acid is present at a concentration of about 0.07 percent by weight;
lactic acid is present at a concentration of about 1.5 percent by weight;
SSA is present at a concentration of about 0.01 percent by weight; and
potassium chlorate is present at a concentration of at least about 0.01 percent by weight.
